(19) United States
(12) Patent Application Publication
(10) Pub. No.: US 2021/0175687 A1
(43) Pub. Date: Jun. 10, 2021

(54) METHOD OF PRODUCING VERTICAL CAVITY SURFACE EMITTING LASER, VERTICAL CAVITY SURFACE EMITTING LASER, DISTANCE SENSOR, AND ELECTRONIC APPARATUS

(71) Applicant: SONY SEMICONDUCTOR SOLUTIONS CORPORATION, KANAGAWA (JP)

(72) Inventor: HIDEKI KIMURA, KANAGAWA (JP)

(21) Appl. No.: 16/768,795

(22) PCT Filed: Oct. 18, 2018
(86) PCT No.: PCT/JP2018/038870

§ 371 Date: Jun. 1, 2020

(30) Foreign Application Priority Data
Dec. 11, 2017 (JP) 2017-236840

(51) Int. Cl. H01S 5/183; H01S 5/02; H01S 5/024; H01S 5/042

(52) U.S. Cl. CPC H01S 5/18369; H01S 5/0215; H01S 5/0421; H01S 5/02453; H01S 5/1838

(57) ABSTRACT

[Object] To provide a method of producing a vertical cavity surface emitting laser exhibiting excellent conductivity/heat-dissipation, the vertical cavity surface emitting laser, a distance sensor, and an electronic apparatus.

[Solving Means] A method of producing a vertical cavity surface emitting laser according to the present technology includes: creating a first substrate by sequentially stacking a dielectric DBR layer and a first dielectric to-be-bonded layer on a support substrate. A second substrate is created by sequentially stacking a semiconductor DBR layer, a current blocking layer, an active layer, a contact layer, and a second dielectric to-be-bonded layer on a semiconductor substrate. The dielectric to-be-bonded layers are bonded to each other. A bonded body of the first substrate and the second substrate is annealed.

### TECHNICAL FIELD

The present technology relates to a method of producing a vertical cavity surface emitting laser that is a semiconductor laser device, the vertical cavity surface emitting laser, a distance sensor, and an electronic apparatus.

### BACKGROUND ART

A vertical cavity surface emitting laser (VCSEL) device is a type of a semiconductor laser device, and is a device that resonates light in a direction orthogonal to a substrate surface and emits laser light in the same direction.

As a structure of the VCSEL device, for example, Non-Patent Literature 1 discloses a VCSEL device that includes a pair of DBRs (Distributed Bragg Reflectors) forming a resonator with a compound semiconductor light-emitting layer sandwiched therebetween.

One of the DBRs is formed by alternately stacking approximately 20 layers having different refractive indexes on a VCSEL device, the Al composition of AlGaAs having been changed between the layers. The other DBR is formed by alternately stacking approximately 20 layers of SiO₂ and Ta₂O₅ on the silicon substrate side.

This VCSEL device is formed by bonding a compound semiconductor substrate on which the above-mentioned DBRs are formed and a silicon substrate with a BCB (benzene cyclobutene) resin.

### CITATION LIST

### Non-Patent Literature

Non-Patent Literature 1: Silicon-Integrated Hybrid-Cavity 850-nm VCSELs by Adhesive Bonding: Impact of Bonding Interface Thickness on Laser Performance, IEEE JOURNAL OF SELECTED TOPICS IN QUANTUM ELECTRONICS, VOL. 23, NO. 6, NOVEMBER/DECEMBER 2017

### DISCLOSURE OF INVENTION

### Technical Problem

However, the VCSEL device described in the above-mentioned Non-Patent Literature 1 has large thermal resistances of the BCB resin and the DBR obtained by stacking SiO₂ and Ta₂O. For this reason, the heat generated by laser emission is less likely to be emitted from the VCSEL device, and there is a possibility that the device characteristics are degraded by high temperatures.

In view of the circumstances as described above, it is an object of the present technology to provide a method of producing a vertical cavity surface emitting laser exhibiting excellent conductivity/heat-dissipation, the vertical cavity surface emitting laser, a distance sensor, and an electronic apparatus.

### Solution to Problem

In order to achieve the above-mentioned object, a method of producing a vertical cavity surface emitting laser according to the present technology includes: creating a first substrate by sequentially stacking a dielectric DBR (Distributed Bragg Reflector) layer and a first dielectric to-be-bonded layer on a support substrate.

A second substrate is created by sequentially stacking a semiconductor DBR layer, a current blocking layer, an active layer, a contact layer, and a second dielectric to-be-bonded layer on a semiconductor substrate.

The dielectric to-be-bonded layers are bonded to each other. A bonded body of the first substrate and the second substrate are annealed.

In accordance with this production method, it is possible to bond the first substrate and the second substrate to each other via the dielectric layers (the first dielectric to-be-bonded layer and the second dielectric to-be-bonded layer) having large thermal conductivity, and improve the conductivity/heat-dissipation of the vertical cavity surface emitting laser.

The step of bonding the first dielectric to-be-bonded layer and the second dielectric to-be-bonded layer to each other may include performing plasma bonding in which the first dielectric to-be-bonded layer and the second dielectric to-be-bonded layer are irradiated with plasma and then the first dielectric to-be-bonded layer and the second dielectric to-be-bonded layer are bonded to each other.

The first dielectric to-be-bonded layer and the second dielectric to-be-bonded layer can be bonded to each other by plasma bonding.

The dielectric DBR layer may be configured by alternately stacking a first layer and a second layer, the first layer being formed of a first material, the second layer being formed of a second material, thermal conductivity of at least one of the first layer or the second layer being 10 W/mK or more.

By forming at least one of the first layer or the second layer constituting the dielectric DBR layer using a material having thermal conductivity of 10 W/mK or more, it is possible to reduce the thermal resistance of the dielectric DBR layer and further improve the conductivity/heat-dissipation of the vertical cavity surface emitting laser.

The dielectric DBR layer may be configured by alternately stacking a first layer and a second layer, the first layer being formed of a first material, the second layer being formed of a second material, a refractive index of at least one of the first layer or the second layer being 2 or more.

By forming at least one of the first layer or the second layer constituting the dielectric DBR layer using a material having a refractive index of 2 or more, it is possible to reduce the necessary thickness, reduce the thermal resistance of the dielectric DBR layer, and further improve the conductivity/heat-dissipation of the vertical cavity surface emitting laser.

The dielectric DBR layer may be configured by alternately stacking a first layer and a second layer, the first layer being formed of a first material, the second layer being formed of a second material, thermal conductivity of at least one of the first layer or the second layer being 10 W/mK or more, a refractive index of at least one of the first layer or the second layer being 2 or more.

The first dielectric to-be-bonded layer may be formed of any of SiO₂, SiON, SiN, and Al₂O₃, and the second dielectric to-be-bonded layer may be formed of the same material as that of the first dielectric to-be-bonded layer.

The first material may be SiO₂, and the second material may be Si₃N₄.

The first material may be Si₃N₄, and the second material may be TiO₂.

The first material may be SiO₂, and the second material may be Ta₂O₅.

The first material may be SiO₂, and the second material may be TiO₂.

In order to achieve the above-mentioned object, a vertical cavity surface emitting laser according to the present technology includes: an integrated body including a support substrate, a dielectric DBR layer, a dielectric to-be-bonded layer, a first contact layer, an active layer, a blocking layer, a semiconductor DBR layer, and a second contact layer.

The dielectric DBR layer is provided on the support substrate.

The dielectric to-be-bonded layer is provided on the dielectric DBR layer.

The first contact layer is provided on the dielectric to-be-bonded layer.

The active layer is provided on the first contact layer.

The blocking layer is provided on the active layer.

The semiconductor DBR layer is provided on the blocking layer.

The second contact layer is provided on the semiconductor DBR layer.

The dielectric DBR layer may be configured by alternately stacking a first layer and a second layer, the first layer being formed of a first material, the second layer being formed of a second material, thermal conductivity of at least one of the first layer or the second layer being 10 W/mK or more.

The dielectric DBR layer may be configured by alternately stacking a first layer and a second layer, the first layer being formed of a first material, the second layer being formed of a second material, a refractive index of at least one of the first layer or the second layer being 2 or more.

The dielectric DBR layer may be configured by alternately stacking a first layer and a second layer, the first layer being formed of a first material, the second layer being formed of a second material, thermal conductivity of at least one of the first layer or the second layer being 10 W/mK or more, a refractive index of at least one of the first layer or the second layer being 2 or more.

In order to achieve the above-mentioned object, a distance sensor according to the present technology includes a vertical cavity surface emitting laser. The vertical cavity surface emitting laser includes an integrated body including a support substrate, a dielectric DBR layer on the support substrate, a dielectric to-be-bonded layer on the dielectric DBR layer, a first contact layer on the dielectric to-be-bonded layer, an active layer on the first contact layer, a blocking layer on the active layer, a semiconductor DBR layer on the blocking layer, and a second contact layer on the semiconductor DBR layer.

In order to achieve the above-mentioned object, an electronic apparatus according to the present technology includes a vertical cavity surface emitting laser.

The vertical cavity surface emitting laser includes an integrated body including a support substrate, a dielectric DBR layer on the support substrate, a dielectric to-be-bonded layer on the dielectric DBR layer, a first contact layer on the dielectric to-be-bonded layer, an active layer on the first contact layer, a blocking layer on the active layer, a semiconductor DBR layer on the blocking layer, and a second contact layer on the semiconductor DBR layer.

### Advantageous Effects of Invention

As described above, in accordance with the present technology, a method of producing a vertical cavity surface emitting laser exhibiting excellent conductivity/heat-dissipation, the vertical cavity surface emitting laser, a distance sensor, and an electronic apparatus are provided.

### BRIEF DESCRIPTION OF DRAWINGS

FIG. 1 is a cross-sectional view of a VCSEL device according to an embodiment of the present technology.

FIG. 2 is a cross-sectional view of a dielectric DBR layer of the VCSEL device.

FIG. 3 is a cross-sectional view of the VCSEL device to which a wiring is connected.

FIG. 4 is a table showing refractive indexes and thermal conductivity of respective materials.

FIG. 5 is a schematic diagram showing a stacked structure of a dielectric DBR layer of the VCSEL device.

FIG. 6 is a table showing materials of the dielectric DBR layer of the VCSEL device (having an emission wavelength of 840 nm), and the structure thereof.

FIG. 7 is a table showing materials of the dielectric DBR layer of the VCSEL device (having an emission wavelength of 940 nm), and the structure thereof.

FIG. 8 is a graph showing simulation results of the reflectance of the VCSEL device (having an emission wavelength of 840 nm).

FIG. 9 is a graph showing simulation results of the reflectance of the VCSEL device (having an emission wavelength of 940 nm).

FIG. 10 is a cross-sectional view of a first substrate used for producing the VCSEL device.

FIG. 11 is a cross-sectional view of a second substrate used for producing the VCSEL device.

FIG. 12 is a schematic diagram showing a method of producing the VCSEL device.

FIG. 13 is a schematic diagram showing the method of producing the VCSEL device.

FIG. 14 is a schematic diagram showing the method of producing the VCSEL device.

FIG. 15 is a schematic diagram showing the method of producing the VCSEL device.

FIG. 16 is a schematic diagram showing the method of producing the VCSEL device.

FIG. 17 is a schematic diagram showing the method of producing the VCSEL device.

FIG. 18 is a schematic diagram showing the method of producing the VCSEL device.

FIG. 19 is a schematic diagram showing the method of producing the VCSEL device.

FIG. 20 is a schematic diagram showing the method of producing the VCSEL device.

FIG. 21 is a schematic diagram showing the method of producing the VCSEL device.

FIG. 22 is a cross-sectional view of a VCSEL device integrated body according to an embodiment of the present technology.

FIG. 23 is a schematic diagram showing a method of producing the VCSEL device integrated body.

FIG. 24 is a schematic diagram showing the method of producing the VCSEL device integrated body.

FIG. 25 is a schematic diagram showing the method of producing the VCSEL device integrated body.

### MODE(S) FOR CARRYING OUT THE INVENTION

A vertical cavity surface emitting laser (VCSEL) device according to an embodiment of the present technology will be described.

[Structure of VCSEL Device]

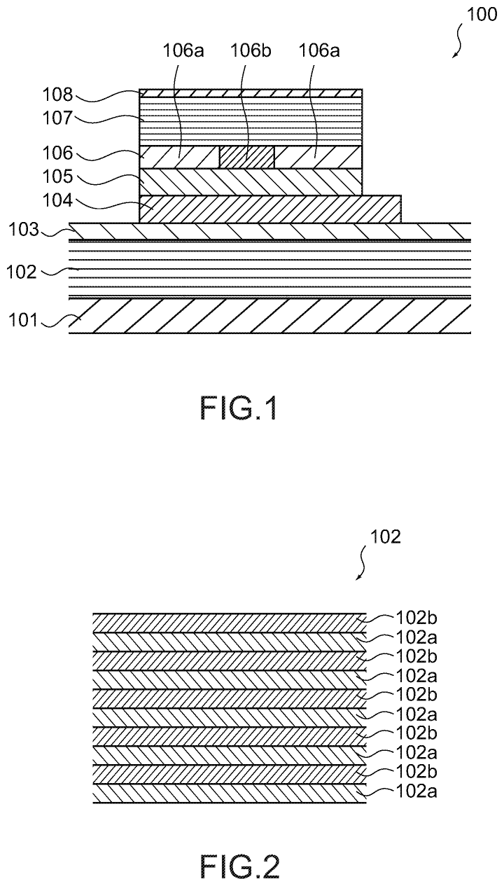

FIG. 1 is a cross-sectional view of a VCSEL device 100 according to this embodiment. As shown in the figure, the VCSEL device 100 is configured by stacking a support substrate 101, a dielectric DBR layer 102, a dielectric to-be-bonded layer 103, a first contact layer 104, an active layer 105, a blocking layer 106, a semiconductor DBR layer 107, and a second contact layer 108 in this order.

The support substrate 101 supports the respective layers of the VCSEL device 100. The support substrate 101 is formed of, for example, Si, Ge, or Al₂O₃.

The dielectric DBR layer 102 is a DBR (Distributed Bragg Reflector) formed of a dielectric. FIG. 2 is a cross-sectional view showing the dielectric DBR layer 102. As shown in the figure, the dielectric DBR layer 102 is configured by alternately stacking a first layer 102a and a second layer 102b. The number of layers of the first layer 102a and the second layer 102b are not limited to the illustrated one. The thickness of the dielectric DBR layer 102 is, for example, 3 μm. The material of the first layer 102a and details of the second layer 102b will be described below.

The dielectric to-be-bonded layer 103 bonds the lower layer structure and the upper layer structure of the dielectric to-be-bonded layer 103. The dielectric to-be-bonded layer 103 is formed of a dielectric, e.g., SiO₂, SiON, SiN, or Al₂O₃.

The first contact layer 104 is formed of an n-type semiconductor material such as n-type GaAs. The thickness of the first contact layer 104 is, for example, 1 to 2 μm.

The active layer 105 is formed by alternately stacking a quantum well layer and a barrier layer, and forms a quantum well, the quantum well layer being formed of GaAs or the like and having a small band gap, the barrier layer being formed of AlGaAs or the like and having a large band gap. The thickness of the active layer 105 is, for example, 0.3 μm.

The blocking layer 106 includes an oxidized area 106a and a non-oxidized area 106b, and applies a blocking effect to a current flowing between the first contact layer 104 and the second contact layer 108.

The oxidized area 106a is formed of oxidized AlGaAs or the like, has low conductivity and a small refractive index, and functions as a light confinement area. The non-oxidized area 106b is formed of non-oxidized AlGaAs or the like, has higher conductivity than the oxidized area 106a, and functions as a current injection area. The thickness of the blocking layer 106 is, for example, 0.15 μm.

The semiconductor DBR layer 107 is a DBR formed of a semiconductor. The semiconductor DBR layer 107 configured by alternately stacking a first layer and a second layer having different refractive indexes. The first layer is formed of, for example, AlₓGa₁₋ₓAs, and the second layer is formed of, for example, AlₓGa₁₋ₓAs having a composition different from that of the first layer. The number of stacked layers of the first layer and the second layer is not particularly limited. The thickness of the semiconductor DBR layer 107 is, for example, 3 μm.

The second contact layer 108 is formed of a p-type semiconductor material such as a p-type GaAs. The thickness of the second contact layer 108 is not particularly limited. However, since laser is transmitted through the second contact layer 108, it is favorable that the thickness of the second contact layer 108 is smaller.

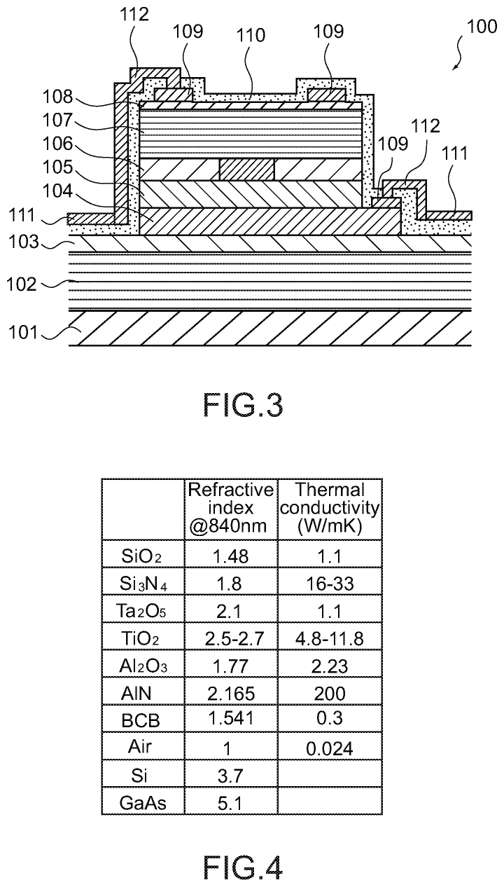

FIG. 3 is a cross-sectional view of the VCSEL device 100 to which a wiring is connected. As shown in the figure, an electrode 109 is formed on each of the first contact layer 104 and the second contact layer 108. The surface of the VCSEL device 100 is covered with an insulation layer 110 formed of an insulation material. A pad 111 is formed on the insulation layer 110, and the electrode 109 and the pad 111 are connected to each other via a wiring 112.

[Operation of VCSEL Device]

The VCSEL device 100 operates in a way similar to that of a general VCSEL device. That is, when a voltage is applied between the first contact layer 104 and the second contact layer 108, a current flows between the first contact layer 104 and the second contact layer 108.

The current is subject to the blocking effect by the blocking layer 106, and injected into the non-oxidized area 106b. Due to this injected current, spontaneous emission light is generated in an area of the active layer 105 close to the non-oxidized area 106b. The spontaneous emission light travels in the stacking direction of the VCSEL device 100 (direction orthogonal to the layers), and is reflected by the dielectric DBR layer 102 and the semiconductor DBR layer 107.

The dielectric DBR layer 102 and the semiconductor DBR layer 107 are configured to reflect light having a specific wavelength (hereinafter, oscillation wavelength). The component of the spontaneous emission light having an oscillation wavelength forms a standing wave between the dielectric DBR layer 102 and the semiconductor DBR layer 107, and is amplified by the active layer 105. In the case where the injected current exceeds a threshold value, the light forming a standing wave performs laser oscillation, and is transmitted through the second contact layer 108 to be emitted.

[Regarding Material of Dielectric DBR Layer]

As described above, the dielectric DBR layer 102 is configured by alternately stacking the first layer 102a and the second layer 102b. Hereinafter, the material of the first layer 102a will be referred to as the first material and the material of the second layer 102b will be referred to as the second material.

It is favorable that the thermal conductivity of at least one of the first material or the second material is 10 W/mK or more. Further, it is favorable that the refractive index of at least one of the first material or the second material is 2 or more. Further, it is more favorable that the thermal conductivity of at least one of the first material or the second material is 10 W/mK or more and the refractive index of at least one of the first material or the second material is 2 or more.

FIG. 4 is a table showing the refractive indexes and thermal conductivity of respective materials. Examples of the material having thermal conductivity of 10 W/mK or more include Si₃N₄, AlN, and TiO₂. Further, examples of the material having a refractive index of 2 or more include Ta₂O₅, TiO₂, AlN, Si, and GaAs.

When the combination of the first material and the second material is described as “the first material/the second material”, SiO₂/Ta₂O₅, SiO₂/Si₃N₄, SiO₂/TiO₂, or Si₃N₄/TiO₂ is favorable.

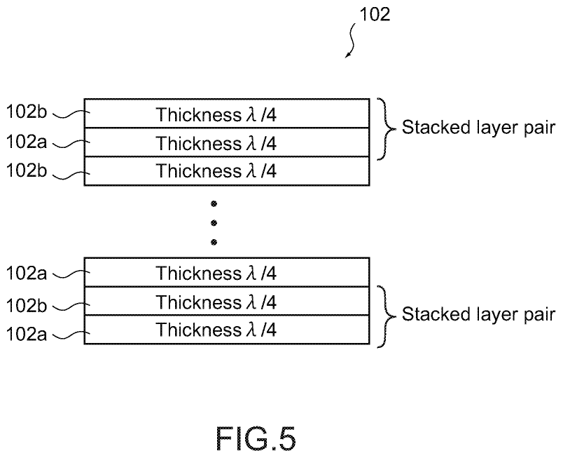

FIG. 5 is a schematic diagram showing a stacked structure of the dielectric DBR layer 102. As shown in the figure, each of the first layer 102a and the second layer 102b has a thickness corresponding to λ/4. A represents the emission wavelength of the VCSEL device 100, the thickness corresponding to λ/4 is determined by the refractive index of the corresponding material. A pair of one first layer 102a and one second layer 102b will be referred to as the stacked layer pair.

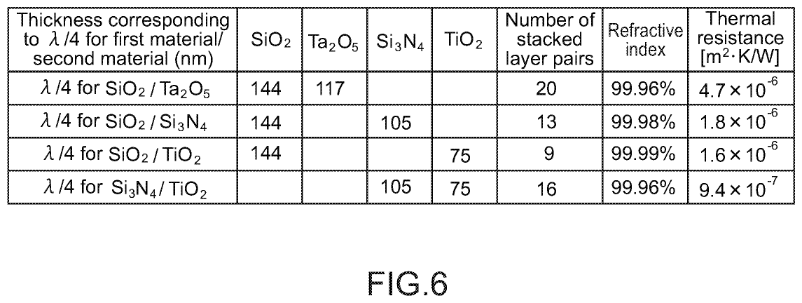

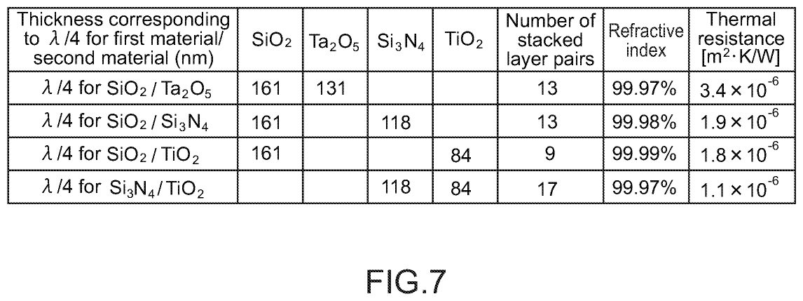

FIG. 6 and FIG. 7 are each a table showing the thickness corresponding to λ/4 for the combination of the first material/the second material, the reflectance, and the thermal resistance. FIG. 6 is a table in the case where an emission wavelength A of the VCSEL device 100 is 840 nm, and FIG. 7 is a table in the case where the emission wavelength A of the VCSEL device 100 is 940 nm.

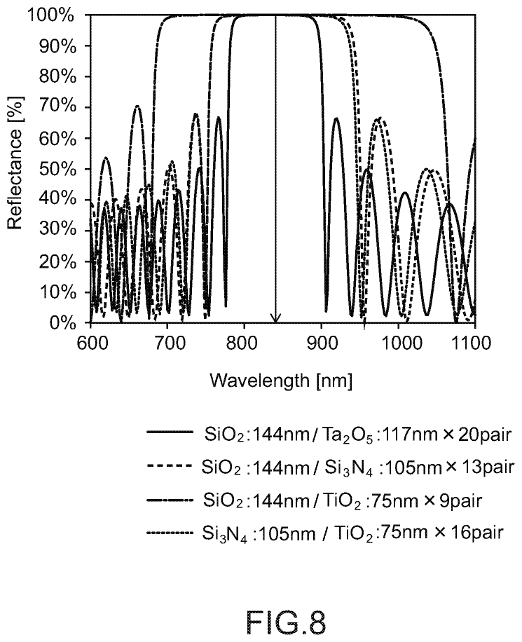

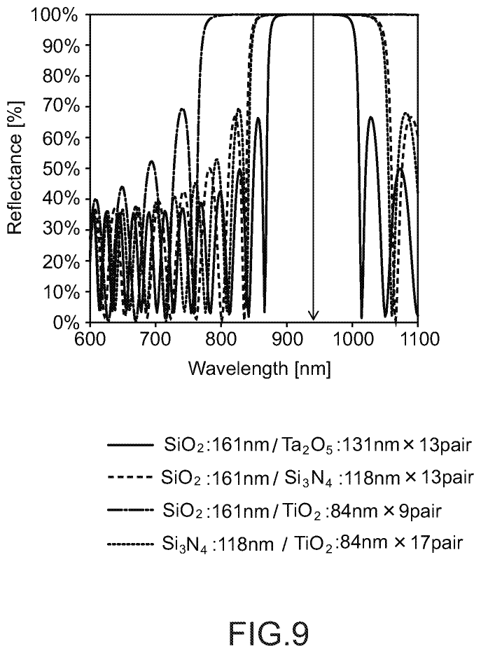

FIG. 8 shows simulation results of the reflectance of the VCSEL device 100 having the emission wavelength A of 840 nm, and FIG. 9 shows simulation results of the reflectance of the VCSEL device 100 having the emission wavelength A of 940 nm.

As shown in FIG. 6, in the case of SiO₂/Ta₂O₅, the thickness corresponding to λ/4 of SiO₂ is 144 nm and the thickness corresponding to λ/4 of Ta₂O₅ is 117 nm. In order to achieve the reflectance of 99.96%, it is necessary to make the number of the stacked layer pairs 20. In this case, the thermal resistance is 4.7×10⁻⁶ m²·K/W, and the thermal resistance of the dielectric DBR layer 102 can be reduced.

Also in the cases of SiO₂/Si₃N₄, SiO₂/TiO₂, and Si₃N₄/TiO₂, the thermal resistance of the dielectric DBR layer 102 can be reduced as shown in FIG. 6 and FIG. 7, and thus, they are favorable as the first material and the second material.

Note that the dielectric DBR layer 102 is not limited to the one obtained by alternately stacking two types of materials, and may be one obtained by alternately stacking three or more types of materials.

Even in this case, it is favorable that the thermal conductivity of at least one of a plurality of materials forming the dielectric DBR layer 102 is 10 W/mK or more. Further, it is favorable that the refractive index of at least one of the plurality of materials is 2 or more. Further, it is more favorable that the thermal conductivity of at least one of the plurality of materials is 10 W/mK or more and the refractive index of at least one of the plurality of materials is 2 or more.

[Method of Producing VCSEL Device]

A method of producing the VCSEL device 100 will be described. The VCSEL device 100 can be produced by preparing the first substrate and the second substrate, and bonding them to each other. Note that in the following description, layers to be the respective layers of the above-mentioned VCSEL device 100 will be denoted by the same reference symbols as those of the respective layers of the VCSEL device 100.

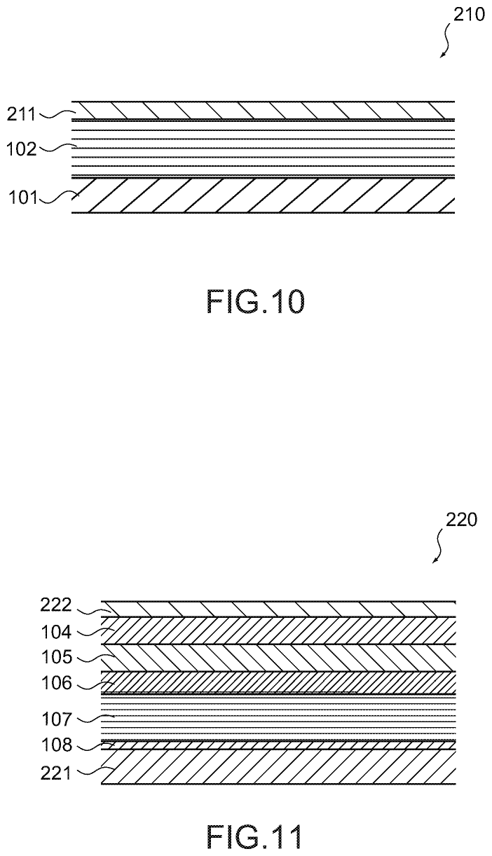

FIG. 10 is a cross-sectional view showing a first substrate 210. As shown in the figure, the first substrate 210 is formed by sequentially stacking the support substrate 101, the dielectric DBR layer 102, and a first dielectric to-be-bonded layer 211.

The dielectric DBR layer 102 can be formed by alternately depositing the first layer 102a and the second layer 102b on the support substrate 101. The deposition of the first layer 102a and the second layer 102b can be performed by a sputtering method, a CVD (chemical vapor deposition) method, or an ALD (Atomic Layer Deposition) method.

The first dielectric to-be-bonded layer 211 is a layer formed of the same material as that of the above-mentioned dielectric to-be-bonded layer 103. The first dielectric to-be-bonded layer 211 can be stacked on the dielectric DBR layer 102 by a sputtering method, a CVD method, or an ALD method.

FIG. 11 is a cross-sectional view showing a second substrate 220. As shown in the figure, the second substrate 220 is formed by sequentially stacking a semiconductor substrate 221, the second contact layer 108, the semiconductor DBR layer 107, the blocking layer 106, the active layer 105, the first contact layer 104, and a second dielectric to-be-bonded layer 222.

The second contact layer 108, the semiconductor DBR layer 107, the blocking layer 106, the active layer 105, and the first contact layer 104 can be stacked on the semiconductor substrate 221 by epitaxial growth by an MOCVD (metal organic chemical vapor deposition) method.

The second dielectric to-be-bonded layer 222 is a layer formed of the same material as that of the above-mentioned dielectric to-be-bonded layer 103. The second dielectric to-be-bonded layer 222 can be stacked on the first contact layer 104 by a sputtering method, a CVD method, or an ALD method.

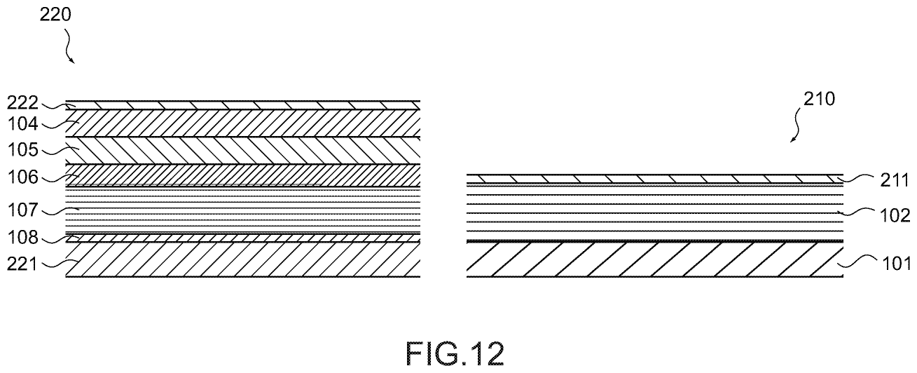

FIG. 12 to FIG. 21 are each a schematic diagram showing the production process of the VCSEL device 100. As shown in FIG. 12, the first dielectric to-be-bonded layer 211 and the second dielectric to-be-bonded layer 222 are flattened at an atomic level. This flattening can be performed by CMP (chemical mechanical polishing).

At this time, in order to achieve a high yield as the VCSEL device 100, it is necessary for the active layer 105 to have an “antinode” of optical resonance, and the thickness variation of the first dielectric to-be-bonded layer 211 and the second dielectric to-be-bonded layer 222 needs to be approximately 50 nm or less. For this reason, it is better to precisely control the flattening while measuring the entire thickness of the first substrate 220 and the second substrate 220.

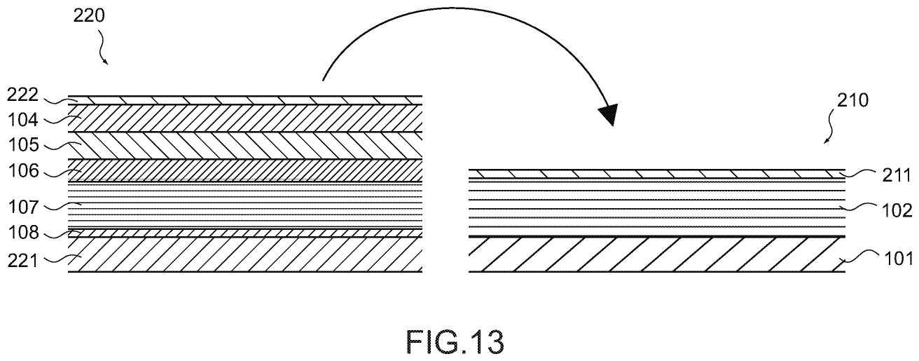

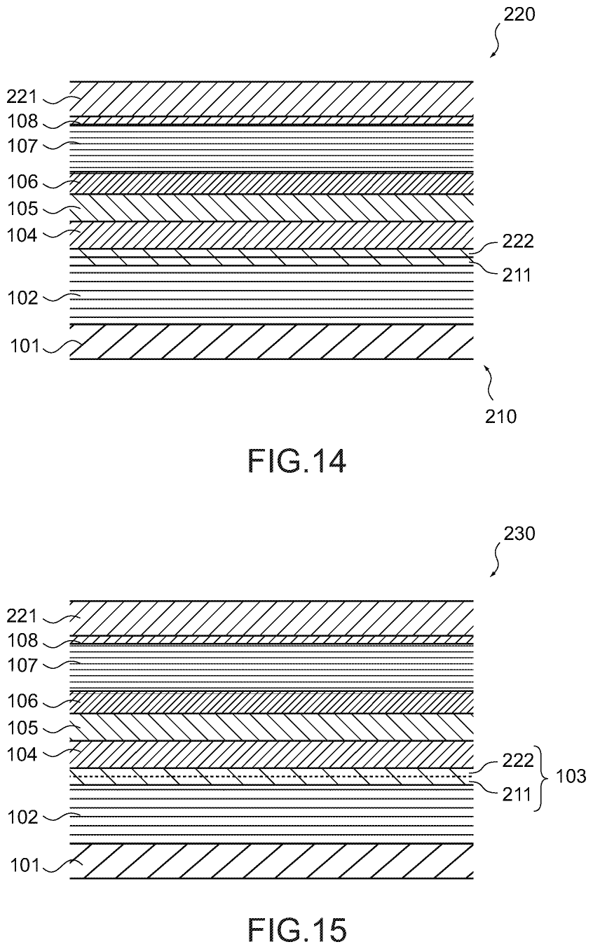

Subsequently, the first dielectric to-be-bonded layer 211 and the second dielectric to-be-bonded layer 222 are irradiated with plasma. By the plasma irradiation, dangling bonds are formed in the first dielectric to-be-bonded layer 211 and the second dielectric to-be-bonded layer 222. Further, as shown in FIG. 13, the first substrate 210 and the second substrate 220 are caused to face each other so that the first dielectric to-be-bonded layer 211 and the second dielectric to-be-bonded layer 222 are adjacent to each other, and thus, the first substrate 210 and the second substrate 220 are brought into contact with each other as shown in FIG. 14.

As a result, as shown in FIG. 15, the first dielectric to-be-bonded layer 211 and the second dielectric to-be-bonded layer 222 are boded to each other (normal-temperature plasma bonding) to form the dielectric to-be-bonded layer 103. In this way, a bonded body 230 of the first substrate 210 and the second substrate 220 is formed.

Subsequently, the bonded body 230 is annealed to strengthen the bonding between the first dielectric to-be-bonded layer 211 and the second dielectric to-be-bonded layer 222. Specifically, by this annealing, the dangling bonds formed by the above-mentioned plasma irradiation form bonding.

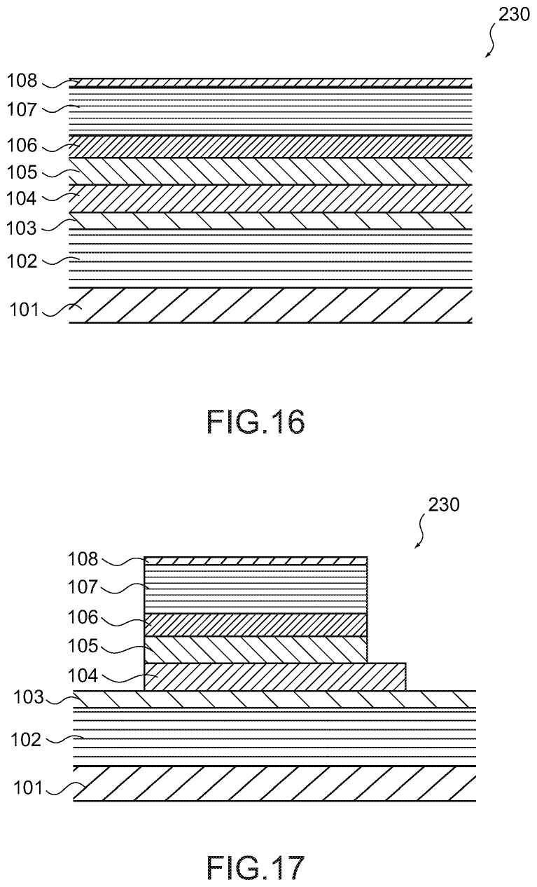

Subsequently, the semiconductor substrate 221 is thinned and removed, leaving the second contact layer 108 as shown in FIG. 16. Further, as shown in FIG. 17, a part of each of the second contact layer 108, the semiconductor DBR layer 107, the blocking layer 106, the active layer 105, and the first contact layer 104 is removed to form a mesa post shape.

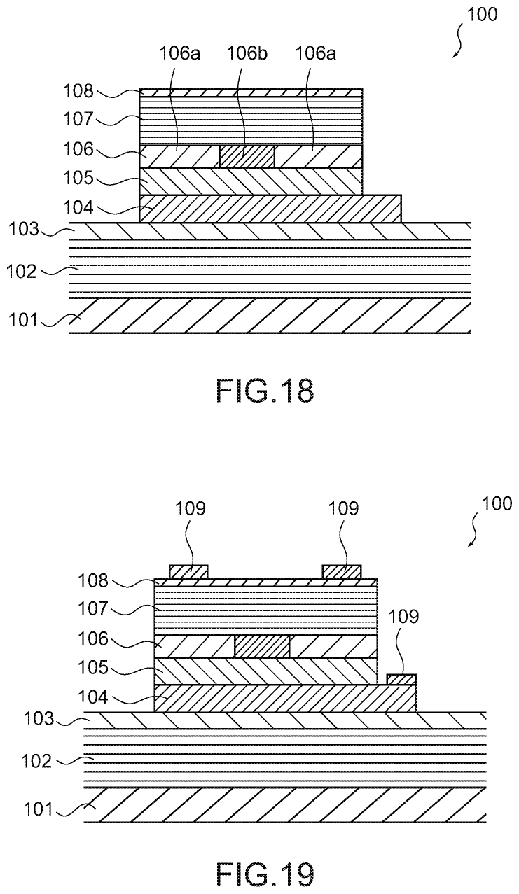

Subsequently, as shown in FIG. 18, oxidation treatment is performed on a part of the blocking layer 106 to form the oxidized area 106a and the non-oxidized area 106b.

Subsequently, as shown in FIG. 19, the electrode 109 is formed on each of the first contact layer 104 and the second contact layer 108. Further, the insulation layer 110, the pad 111, and the wiring 112 are formed (see FIG. 3).

The VCSEL device 100 can be produced in this way. Note that although the second contact layer 108 is formed on the semiconductor substrate 221 in the above description, the second contact layer 108 may be formed after bonding.

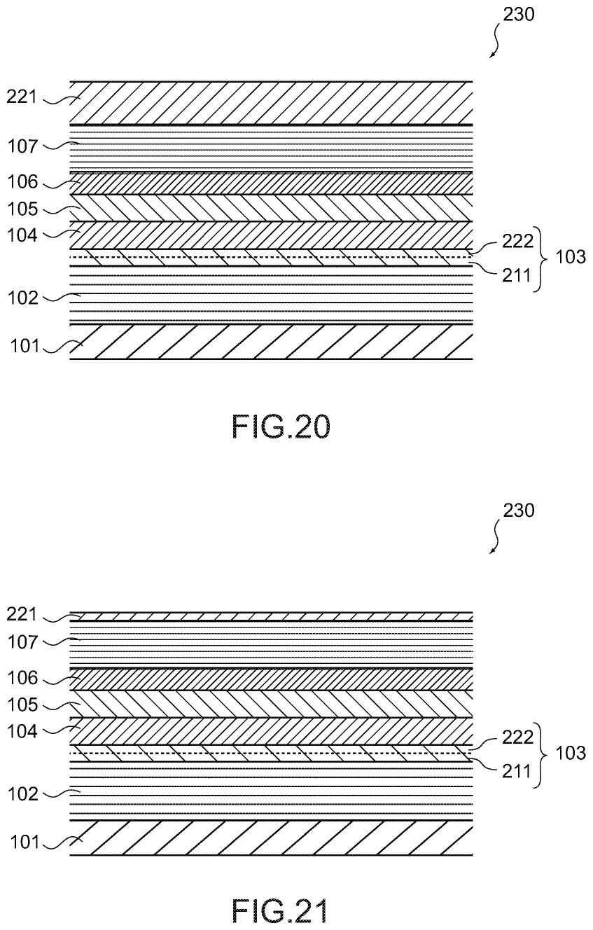

In this case, as shown in FIG. 20, the one obtained by directly stacking the semiconductor DBR layer 107 on the semiconductor substrate 221 is used as the second substrate 220, and the semiconductor substrate 221 is thinned as shown in FIG. 21. Further, the thinned semiconductor substrate 221 can be doped with impurities to obtain the second contact layer 108 shown in FIG. 16.

[Regarding Effect by VCSEL Device]

The VCSEL device 100 has the configuration described above. As described above, the VCSEL device 100 is formed by bonding the first substrate 210 and the second substrate 220 via the dielectric to-be-bonded layer 103. The dielectric to-be-bonded layer 103 is formed of a dielectric material having high thermal conductivity such as SiO₂, and capable of increasing the conductivity/heat-dissipation of the VCSEL device 100.

Further, by using the above-mentioned materials as the materials (the first material and the second material) of the dielectric DBR layer 102, it is possible to reduce the thermal resistance of the dielectric DBR layer 102 and improve the conductivity/heat-dissipation of the VCSEL device 100.

The VCSEL device 100 can be used as a light-emitting device of a distance sensor used for face recognition or the like in various electronic apparatuses such as a smartphone.

[Regarding VCSEL Integrated Body]

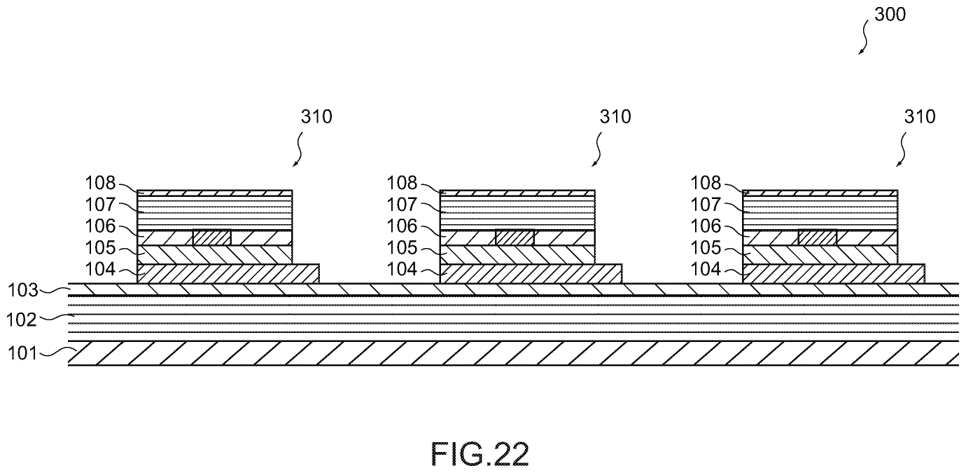

The VCSEL device 100 can be used as an integrated body. FIG. 22 is a cross-sectional view of a VCSEL integrated body 300 that is an integrated body of VCSEL devices.

As shown in the figure, the VCSEL integrated body 300 includes a plurality of VCSEL devices 310. Each of the VCSEL devices 310 includes the same layer structure as that of the VCSEL device 100, and the support substrate 101, the dielectric DBR layer 102, and the dielectric to-be-bonded layer 103 are common to the plurality of VCSEL devices 310.

The number and arrangement of the VCSEL devices 310 are not particularly limited, and the VCSEL devices 310 may be arranged in a one-dimensional array or a two-dimensional array. By integrating the VCSEL devices 310, it is possible to form high-power laser.

[Regarding Method of Producing VCSEL Integrated Body]

The method of producing the VCSEL integrated body 300 will be described. The VCSEL integrated body 300 can be produced by a production process similar to that of the VCSEL device 100. That is, the first substrate 210 and the second substrate 220 are bonded to each other (see FIG. 10 to FIG. 15), the semiconductor substrate 221 is thinned (see FIG. 16), and then, a mesa post shape is formed (see FIG. 17).

At this time, by forming a plurality of mesa posts separated from each other and forming the oxidized area 106a and the non-oxidized area 106b (see FIG. 18), the respective mesa posts are obtained as the VCSEL devices 310. It is possible to produce the VCSEL integrated body 300 including a plurality of VCSEL devices 310 from the bonded body 230 in which one first substrate 210 and one second substrate 220 are bonded to each other.

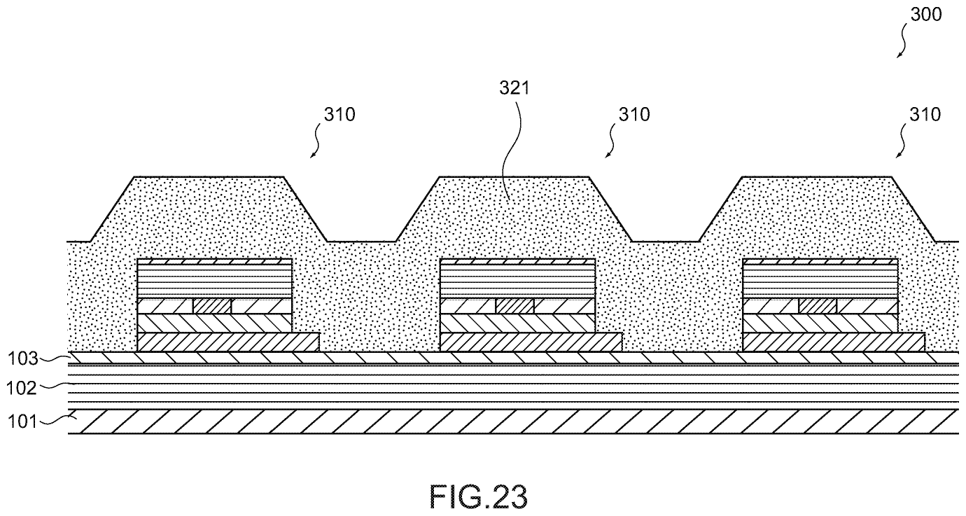

FIG. 23 to FIG. 25 are each a schematic diagram showing the method of forming a wiring and an embedding film of the VCSEL integrated body 300. As shown in FIG. 23, an embedding film 321 is formed on the VCSEL integrated body 300. The embedding film 321 can be, for example, SiO₂, and can be deposited by CVD or the like.

Further, the embedding film 321 may be formed of inorganic water glass by SOG (Spin on Glass) or the like, or may be formed by spin-coating an organic polymer such as BCB (benzene cyclobutene) and polyimide. The thickness of the embedding film 321 is favorably approximately 1.5 times the height of the VCSEL devices 310 (height from the dielectric to-be-bonded layer 103 to the second contact layer 108).

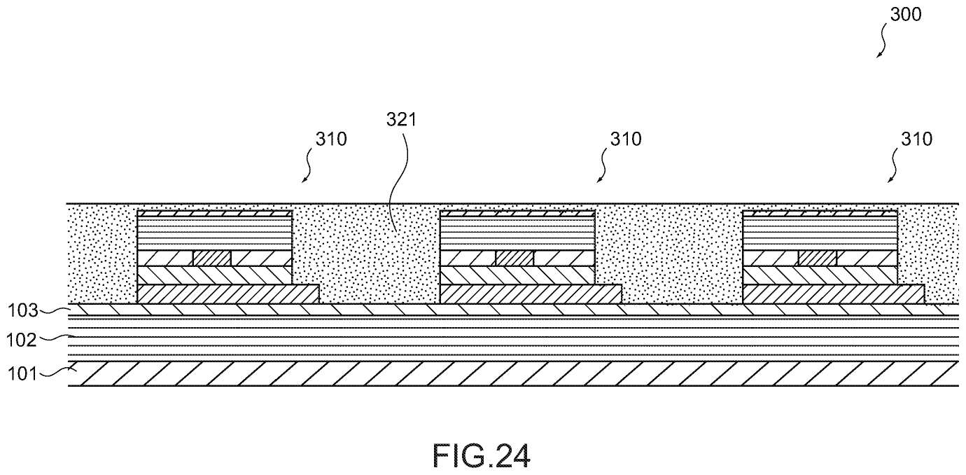

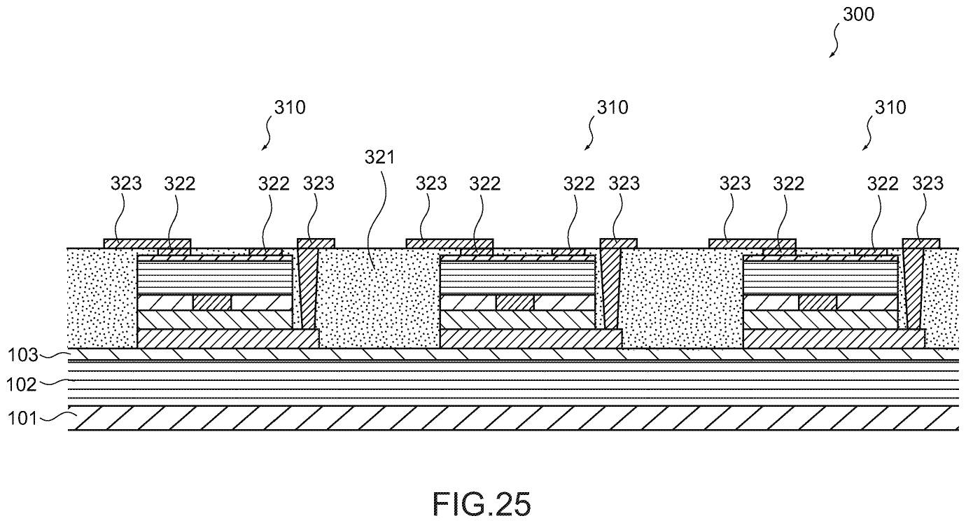

Subsequently, as shown in FIG. 24, the embedding film 321 is flattened. The flattening can be performed by, for example, CMP. Subsequently, contact holes are formed in the embedding film 321, and electrodes 322 and wirings 323 are formed as shown in FIG. 25. In this way, the wiring and the embedding film can be formed in the VCSEL integrated body 300.

Since the embedding film 321 flattens the surface of the VCSEL integrated body 300 and makes it easy to form the wirings 323, it is possible to improve the wiring yield.

[Regarding Optoelectronic Integrated Circuit]

By providing a diffraction grating on the dielectric DBR layer 102, an optoelectronic integrated circuit can be configured by the VCSEL device 100. In this case, after forming the dielectric DBR layer 102 in the first substrate 210 (see FIG. 10), it only needs to form a diffraction grating on the dielectric DBR layer 102 and provide the first dielectric to-be-bonded layer 211 thereon. The laser generated in the VCSEL device 100 is guided into the optical integrated circuit by this diffraction grating.

It should be noted that the present technology may take the following configurations.

(1)

A method of producing a vertical cavity surface emitting laser, including:

creating a first substrate by sequentially stacking a dielectric DBR (Distributed Bragg Reflector) layer and a first dielectric to-be-bonded layer on a support substrate;

creating a second substrate by sequentially stacking a semiconductor DBR layer, a current blocking layer, an active layer, a contact layer, and a second dielectric to-be-bonded layer on a semiconductor substrate;

bonding the first dielectric to-be-bonded layer and the second dielectric to-be-bonded layer to each other; and

annealing a bonded body of the first substrate and the second substrate.

(2)

The method of producing a vertical cavity surface emitting laser according to (1) above, in which

the step of bonding the first dielectric to-be-bonded layer and the second dielectric to-be-bonded layer to each other includes performing plasma bonding in which the first dielectric to-be-bonded layer and the second dielectric to-be-bonded layer are irradiated with plasma and then the first dielectric to-be-bonded layer and the second dielectric to-be-bonded layer are bonded to each other.

(3)

The method of producing a vertical cavity surface emitting laser according to (1) or (2) above, in which

the dielectric DBR layer is configured by alternately stacking a first layer and a second layer, the first layer being formed of a first material, the second layer being formed of a second material, thermal conductivity of at least one of the first layer or the second layer being 10 W/mK or more.

(4)

The method of producing a vertical cavity surface emitting laser according to (1) or (2) above, in which

the dielectric DBR layer is configured by alternately stacking a first layer and a second layer, the first layer being formed of a first material, the second layer being formed of a second material, a refractive index of at least one of the first layer or the second layer being 2 or more.

(5)

The method of producing a vertical cavity surface emitting laser according to (1) or (2) above, in which

the dielectric DBR layer is configured by alternately stacking a first layer and a second layer, the first layer being formed of a first material, the second layer being formed of a second material, thermal conductivity of at least one of the first layer or the second layer being 10 W/mK or more, a refractive index of at least one of the first layer or the second layer being 2 or more.

(6)

The method of producing a vertical cavity surface emitting laser according to any one of (1) to (5) above, in which

the first dielectric to-be-bonded layer is formed of any of SiO₂, SiON, SiN, and Al₂O₃, and

the second dielectric to-be-bonded layer is formed of the same material as that of the first dielectric to-be-bonded layer.

(7)

The method of producing a vertical cavity surface emitting laser according to any one of (1) to (6) above, in which

the first material is SiO₂, and

the second material is Si₃N₄.

(8)

The method of producing a vertical cavity surface emitting laser according to any one of (1) to (6) above, in which

the first material is Si₃N₄, and

the second material is TiO₂.

(9)

The method of producing a vertical cavity surface emitting laser according to any one of (1) to (6) above, in which

the first material is SiO₂, and

the second material is Ta₂O₅.

(10)

The method of producing a vertical cavity surface emitting laser according to any one of (1) to (6) above, in which

the first material is SiO₂, and

the second material is TiO₂.

(11)

A vertical cavity surface emitting laser, including

an integrated body including
a support substrate,
a dielectric DBR layer on the support substrate,
a dielectric to-be-bonded layer on the dielectric DBR layer,
a first contact layer on the dielectric to-be-bonded layer,
an active layer on the first contact layer,
a blocking layer on the active layer,
a semiconductor DBR layer on the blocking layer, and
a second contact layer on the semiconductor DBR layer.

(12)

The vertical cavity surface emitting laser according to (11) above, in which

the dielectric DBR layer is configured by alternately stacking a first layer and a second layer, the first layer being formed of a first material, the second layer being formed of a second material, thermal conductivity of at least one of the first layer or the second layer being 10 W/mK or more.

(13)

The vertical cavity surface emitting laser according to (11) above, in which

the dielectric DBR layer is configured by alternately stacking a first layer and a second layer, the first layer being formed of a first material, the second layer being formed of a second material, a refractive index of at least one of the first layer or the second layer being 2 or more.

(14)

The vertical cavity surface emitting laser according to (11) above, in which

the dielectric DBR layer is configured by alternately stacking a first layer and a second layer, the first layer being formed of a first material, the second layer being formed of a second material, thermal conductivity of at least one of the first layer or the second layer being 10 W/mK or more, a refractive index of at least one of the first layer or the second layer being 2 or more.

(15)

A distance sensor, including

a vertical cavity surface emitting laser that includes an integrated body including

a support substrate,

a dielectric DBR layer on the support substrate,

a dielectric to-be-bonded layer on the dielectric DBR layer,

a first contact layer on the dielectric to-be-bonded layer,

an active layer on the first contact layer,

a blocking layer on the active layer,

a semiconductor DBR layer on the blocking layer, and

a second contact layer on the semiconductor DBR layer.

(16)

An electronic apparatus, including

a vertical cavity surface emitting laser that includes an integrated body including

a support substrate,

a dielectric DBR layer on the support substrate,

a dielectric to-be-bonded layer on the dielectric DBR layer,

a first contact layer on the dielectric to-be-bonded layer,

an active layer on the first contact layer,

a blocking layer on the active layer,

a semiconductor DBR layer on the blocking layer, and

a second contact layer on the semiconductor DBR layer.

### REFERENCE SIGNS LIST

100 VCSEL device
101 support substrate
102 dielectric DBR layer
102a first layer
102b second layer
103 dielectric to-be-bonded layer
104 first contact layer
105 active layer
106 blocking layer
106a oxidized area
106b non-oxidized area
107 semiconductor DBR layer
108 second contact layer
210 first substrate
211 first dielectric to-be-bonded layer
220 second substrate
221 semiconductor substrate
222 second dielectric to-be-bonded layer
230 bonded body
300 VCSEL integrated body
310 VCSEL device

1. A method of producing a vertical cavity surface emitting laser, comprising:
creating a first substrate by sequentially stacking a dielectric DBR (Distributed Bragg Reflector) layer and a first dielectric to-be-bonded layer on a support substrate;
creating a second substrate by sequentially stacking a semiconductor DBR layer, a current blocking layer, an active layer, a contact layer, and a second dielectric to-be-bonded layer on a semiconductor substrate;
bonding the first dielectric to-be-bonded layer and the second dielectric to-be-bonded layer to each other; and
annealing a bonded body of the first substrate and the second substrate.

2. The method of producing a vertical cavity surface emitting laser according to claim 1, wherein
the step of bonding the first dielectric to-be-bonded layer and the second dielectric to-be-bonded layer to each other includes performing plasma bonding in which the first dielectric to-be-bonded layer and the second dielectric to-be-bonded layer are irradiated with plasma and then the first dielectric to-be-bonded layer and the second dielectric to-be-bonded layer are bonded to each other.

3. The method of producing a vertical cavity surface emitting laser according to claim 1, wherein
the dielectric DBR layer is configured by alternately stacking a first layer and a second layer, the first layer being formed of a first material, the second layer being formed of a second material, thermal conductivity of at least one of the first layer or the second layer being 10 W/mK or more.

4. The method of producing a vertical cavity surface emitting laser according to claim 1, wherein
the dielectric DBR layer is configured by alternately stacking a first layer and a second layer, the first layer being formed of a first material, the second layer being formed of a second material, a refractive index of at least one of the first layer or the second layer being 2 or more.

5. The method of producing a vertical cavity surface emitting laser according to claim 1, wherein
the dielectric DBR layer is configured by alternately stacking a first layer and a second layer, the first layer being formed of a first material, the second layer being formed of a second material, thermal conductivity of at least one of the first layer or the second layer being 10 W/mK or more, a refractive index of at least one of the first layer or the second layer being 2 or more.

6. The method of producing a vertical cavity surface emitting laser according to claim 1, wherein
the first dielectric to-be-bonded layer is formed of any of SiO₂, SiON, SiN, and Al₂O₃, and
the second dielectric to-be-bonded layer is formed of the same material as that of the first dielectric to-be-bonded layer.

7. The method of producing a vertical cavity surface emitting laser according to claim 3, wherein
the first material is SiO₂, and
the second material is Si₃N₄.

8. The method of producing a vertical cavity surface emitting laser according to claim 3, wherein
the first material is Si₃N₄, and
the second material is TiO₂.

9. The method of producing a vertical cavity surface emitting laser according to claim 4, wherein
the first material is SiO₂, and
the second material is Ta₂O₅.

10. The method of producing a vertical cavity surface emitting laser according to claim 4, wherein
the first material is SiO₂, and
the second material is TiO₂.

11. A vertical cavity surface emitting laser, comprising
an integrated body including
a support substrate,
a dielectric DBR layer on the support substrate,
a dielectric to-be-bonded layer on the dielectric DBR layer,
a first contact layer on the dielectric to-be-bonded layer,
an active layer on the first contact layer,
a blocking layer on the active layer,
a semiconductor DBR layer on the blocking layer, and
a second contact layer on the semiconductor DBR layer.

12. The vertical cavity surface emitting laser according to claim 11, wherein
the dielectric DBR layer is configured by alternately stacking a first layer and a second layer, the first layer being formed of a first material, the second layer being formed of a second material, thermal conductivity of at least one of the first layer or the second layer being 10 W/mK or more.

13. The vertical cavity surface emitting laser according to claim 11, wherein
the dielectric DBR layer is configured by alternately stacking a first layer and a second layer, the first layer being formed of a first material, the second layer being formed of a second material, a refractive index of at least one of the first layer or the second layer being 2 or more.

14. The vertical cavity surface emitting laser according to claim 11, wherein
the dielectric DBR layer is configured by alternately stacking a first layer and a second layer, the first layer being formed of a first material, the second layer being formed of a second material, thermal conductivity of at least one of the first layer or the second layer being 10 W/mK or more, a refractive index of at least one of the first layer or the second layer being 2 or more.

15. A distance sensor, comprising
a vertical cavity surface emitting laser that includes an integrated body including
a support substrate,
a dielectric DBR layer on the support substrate,
a dielectric to-be-bonded layer on the dielectric DBR layer,
a first contact layer on the dielectric to-be-bonded layer,
an active layer on the first contact layer,
a blocking layer on the active layer,
a semiconductor DBR layer on the blocking layer, and
a second contact layer on the semiconductor DBR layer.

16. An electronic apparatus, comprising
a vertical cavity surface emitting laser that includes an integrated body including
a support substrate,
a dielectric DBR layer on the support substrate,
a dielectric to-be-bonded layer on the dielectric DBR layer,
a first contact layer on the dielectric to-be-bonded layer,
an active layer on the first contact layer,
a blocking layer on the active layer,
a semiconductor DBR layer on the blocking layer, and
a second contact layer on the semiconductor DBR layer.
